(19) United States
(12) Patent Application Publication
(10) Pub. No.: US 2021/0066895 A1
(43) Pub. Date: Mar. 4, 2021

(54) ELECTRICAL CONNECTION BOX AND FUSIBLE LINK

(71) Applicant: SUMITOMO WIRING SYSTEMS, LTD., Mie (JP)

(72) Inventor: Takashi SHIRAKI, Mie (JP)

(21) Appl. No.: 16/998,767

(22) Filed: Aug. 20, 2020

(30) Foreign Application Priority Data
Aug. 27, 2019 (JP) 2019-154909

(51) Int. Cl. H02B 1/48; H01R 13/68; H01R 25/16; H01R 11/01; H01R 11/28

(52) U.S. Cl. CPC H02B 1/48; H01R 13/68; H01R 25/16; B60R 16/02; H01R 11/281; H01R 2201/26; H01R 11/01

(57) ABSTRACT

Provided is an electrical connection box with high versatility. A relay box includes a fusible link including a power distribution bus bar 32 having a first terminal portion 33 that is to be connected to a battery and third terminal portions 35 and 36 that are to be connected to the first terminal portion 33 via fusing portions 38a, 38b, and 38c, a case 31 that contains at least the fusing portions of the power distribution bus bar 32, and a housing including a fusible link mounting portion on which a fusible link 21 is mounted. The relay box includes a relief terminal portion 40 that can be attached and detached on the first terminal portion 33 side with respect to the fusing portions 38a, 38b, and 38c of the power distribution bus bar 32, and that is for connecting a booster cable.

### CROSS-REFERENCE TO RELATED APPLICATIONS

This application is based on and claims priority from Japanese Patent Application No. 2019-154909, filed on Aug. 27, 2019, with the Japan Patent Office, the disclosure of which is incorporated herein in its entirety by reference.

### TECHNICAL FIELD

The present disclosure relates to an electrical connection box and a fusible link.

### BACKGROUND

Conventionally, an electrical connection box has been proposed which includes a relief terminal portion on which a booster cable to be used when a battery is dead can be mounted (e.g., see Japanese Patent Laid-open Publication No. 2018-026967). In a vehicle such as a hybrid automobile in which no battery is installed in the engine room of the vehicle, a relief terminal portion is included on an electrical connection box such as a relay box, which is installed in the engine room. With the electrical connection box of Japanese Patent Laid-open Publication No. 2018-026967, an exposed portion is used as a relief terminal portion due to a portion of a power distribution bus bar included in a fusible link mounted in the electrical connection box being exposed to the outside.

Incidentally, with the above-described electrical connection box, although a relief terminal portion for connecting a booster cable is included, there is no need to provide the relief terminal portion if, for example, there is a battery at an easily-accessible position such as the engine room. That is, there is still room for improvement in terms of versatility.

An object of the present disclosure is to provide an electrical connection box and a fusible link with high versatility.

### SUMMARY

An electrical connection box of the present disclosure includes: a fusible link including a power distribution bus bar having a power input terminal portion to be connected to a battery and a power branching terminal portion to be connected to the power input terminal portion via a fusing portion, and a case containing at least the fusing portion of the power distribution bus bar; a housing including a fusible link mounting portion for mounting the fusible link; and a relief terminal portion that can be attached and detached on the power input terminal portion side with respect to the fusing portion of the power distribution bus bar, and that is for connecting a booster cable.

A fusible link of the present disclosure includes: a power distribution bus bar including a power input terminal portion to be connected to a battery and a power branching terminal portion to be connected to the power input terminal portion via a fusing portion; and a case that contains at least the fusing portion of the power distribution bus bar. The case has an insertion hole through which a relief terminal portion for connecting a booster cable can be inserted.

According to the electrical connection box of the present disclosure, it is possible to provide an electrical connection box and a fusible link with high versatility.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram showing a schematic configuration of an electrical connection box according to an embodiment.

FIG. 2 is a perspective view of a fuse block according to the embodiment.

FIG. 3 is a perspective view showing the fuse block and a booster cable according to the embodiment.

FIG. 4 is a perspective view showing a state in which a fusible link and a relief terminal portion according to the embodiment are attached to each other.

FIG. 5 is an exploded perspective view of the fusible link and the relief terminal portion according to the embodiment.

FIG. 6 is a front view of the fusible link and the relief terminal portion according to the embodiment.

FIG. 7 is a cross-sectional view showing a fastened state of the fusible link and the relief terminal portion according to the embodiment.

FIG. 8 is a perspective view showing a state in which a fusible link and a relief terminal portion according to a modified example are attached to each other.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

[Description of the Embodiments of the Disclosure]

First, embodiments of the present disclosure will be listed and described.

[1] An electrical connection box of the present disclosure includes: a fusible link including a power distribution bus bar having a power input terminal portion to be connected to a battery and a power branching terminal portion to be connected to the power input terminal portion via a fusing portion, and a case containing at least the fusing portion of the power distribution bus bar; a housing including a fusible link mounting portion for mounting the fusible link; and a relief terminal portion that can be attached and detached on the power input terminal portion side with respect to the fusing portion of the power distribution bus bar, and that is for connecting a booster cable.

According to this configuration, the relief terminal portion for connecting the booster cable can be made attachable and detachable on the power input terminal portion side with respect to the fusing portion of the power distribution bus bar, and thereby the electrical connection box can be used in a state where the relief terminal portion is disconnected if it is not needed. For this reason, versatility can be increased.

[2] It is preferable that the case has an insertion hole through which the relief terminal portion can be inserted.

With this configuration, the relief terminal portion is inserted through the insertion hole of the case, and therefore the relief terminal portion can be stably held by the case.

[3] It is preferable that the power distribution bus bar is fixed by being fastened jointly with the relief terminal portion at the power input terminal portion.

According to this configuration, since the relief terminal portion and the power input terminal portion are fixed to each other through joint fastening, a separate configuration for electrically connecting the relief terminal portion to the battery is not needed, and therefore the configuration can be made simple.

[4] It is preferable that the power distribution bus bar has an opposing surface that opposes the relief terminal portion and has a flat shape.

According to this configuration, the opposing surface of the power distribution bus bar that opposes the relief terminal portion has a flat shape, and therefore the relief terminal portion and the opposing surface can be brought into surface contact with each other when the relief terminal portion is mounted on the power distribution bus bar. Also, due to the opposing surface of the power distribution bus bar being flat, it is possible to suppress a case in which the relief terminal portion is hindered by the power distribution bus bar when the relief terminal portion is inserted through the insertion hole.

[5] It is preferable that an extended fuse part is provided in one piece with the relief terminal portion.

According to this configuration, the extended fuse part is provided in one piece with the relief terminal portion, and therefore the number of fuse parts that are installed can be increased.

[6] It is preferable that the housing includes a fuse mounting portion on which a general-purpose fuse part that is different from the extended fuse part can be mounted, and the extended fuse part is provided at a position that does not overlap with the fuse mounting portion in a state in which the relief terminal portion is mounted on the power distribution bus bar.

According to this configuration, the extended fuse part is provided at a position that does not overlap with the fuse mounting portion, and therefore it is possible to suppress a case in which mounting of a general-purpose fuse part is hindered by the extended fuse part.

[7] It is preferable that the fusible link is mounted by sliding on the fusible link mounting portion, and the relief terminal portion and the extended fuse part are arranged at positions overlapping in a slide direction of the fusible link.

According to this configuration, the relief terminal portion and the extended fuse part overlap with each other in the direction in which the fusible link is mounted by sliding, and therefore the relief terminal portion and the extended fuse part no longer overlap with the general-purpose fuse part and the fuse mounting portion, and it is possible to suppress a case in which the mounting of the general-purpose fuse part is hindered by the relief terminal portion and the extended fuse part.

[8] Also, a fusible link of the present disclosure includes: a power distribution bus bar including a power input terminal portion to be connected to a battery and a power branching terminal portion to be connected to the power input terminal portion via a fusing portion; and a case that contains at least the fusing portion of the power distribution bus bar. The case has an insertion hole through which a relief terminal portion for connecting a booster cable can be inserted.

According to this configuration, the case includes the insertion hole through which a relief terminal portion for connecting a booster cable can be inserted, and therefore it is possible to mount and detach a relief terminal portion, and versatility can be increased.

[Detailed Description of the Embodiments of the Disclosure]

A specific example of an electrical connection box of the present disclosure will be described with reference to the drawings below. In the drawings, for the sake of convenience in the description, parts of the configuration will be shown exaggerated or omitted in some cases. Also, dimensional proportions of the portions differ in the drawings in some cases. Note that the present invention is not limited to these illustrative examples, but is indicated by the scope of the claims, and all changes that fall within the meaning and range of equivalency of the scope of the claims are intended to be encompassed therein.

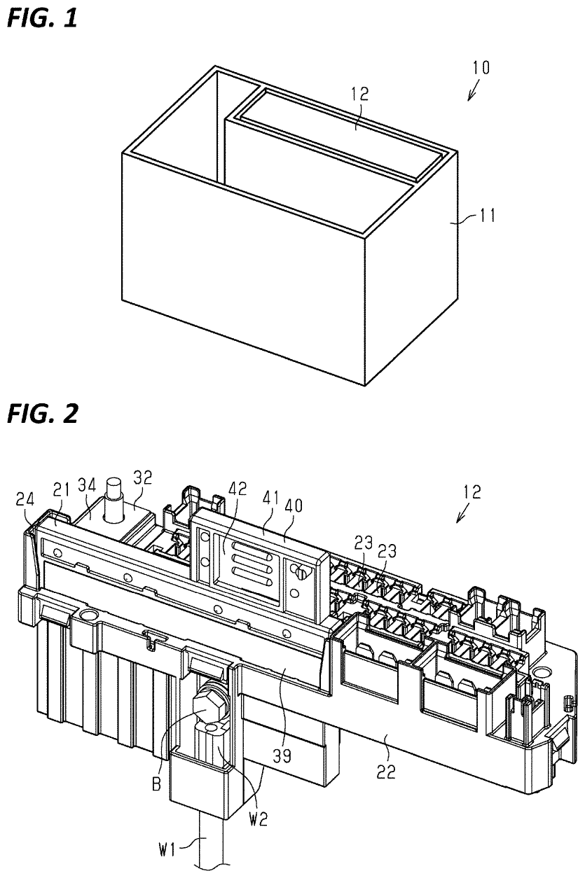

As shown in FIG. 1, in a relay box 10 serving as an electrical connection box of the present embodiment, a fuse block 12 and a relay block (not shown) are contained in a cuboid housing 11. The relay block has a relay part (not shown). The housing 11 has a shape with an opening formed at its upper portion, and the opening and the fuse block 12 are covered by a cover (not shown). The housing 11 is constituted by an insulating synthetic resin material. The housing 11 is molded through, for example, injection molding.

As shown in FIG. 2, the fuse block 12 includes general-purpose fuses (not shown), a fusible link 21 through which a larger current than in the general-purpose fuses flows, and a fuse case 22 for holding the general-purpose fuses and the fusible link 21.

The fuse case 22 is constituted by an insulating synthetic resin material such as polypropylene (PP) or polyamide (PA).

The fuse case 22 includes first mounting portions 23 on which general-purpose fuses can be mounted, and a second mounting portion 24 on which the fusible link 21 can be mounted.

Multiple first mounting portions 23 are provided in the fuse case 22. The general-purpose fuses mounted on the first mounting portions 23 are for preventing excess current from flowing to devices to which a relatively low current is to be supplied.

One second mounting portion 24 is provided in the fuse case 22. The second mounting portion 24 includes an accommodation space in which the fusible link 21, which is larger in size than the general-purpose fuses mounted on the first mounting portions 23, can be mounted. That is, the space inside of the second mounting portion 24 is larger than the space inside of the first mounting portion 23.

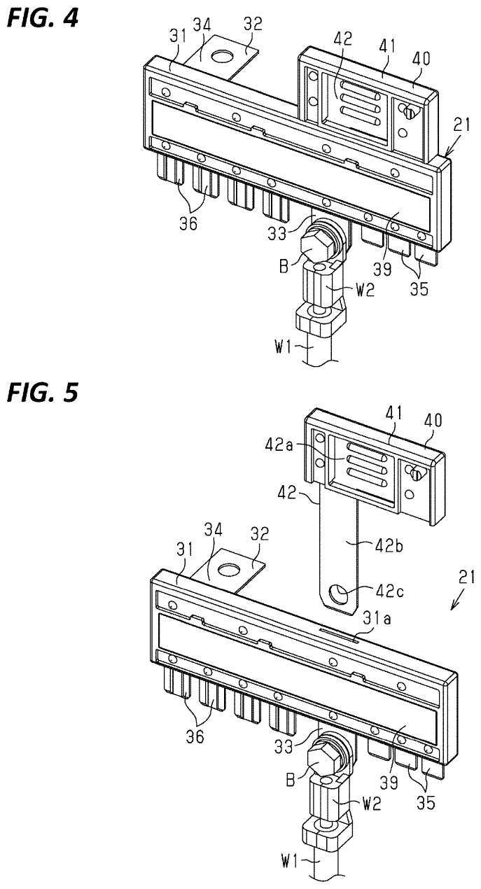

As shown in FIGS. 4, 5, and 6, the fusible link 21 includes a case 31 and a power distribution bus bar 32.

The case 31 is formed so as to have a cuboid shape that is elongated in one direction, and accommodates and holds a portion of the power distribution bus bar 32.

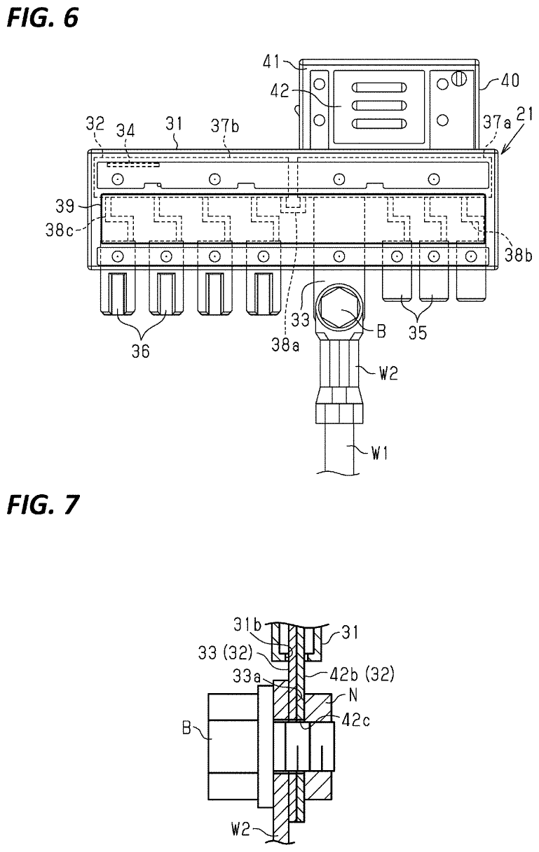

As shown in FIG. 6, the power distribution bus bar 32 has a metal plate shape. The power distribution bus bar 32 has a first terminal portion 33, a second terminal portion 34, third terminal portions 35 and 36, two plate-shaped conducting portions 37a and 37b, and fusing portions 38a, 38b, and 38c.

The first terminal portion 33 is electrically connected to, for example, a battery (not shown). The first terminal portion 33 is exposed from the case 31. The first terminal portion 33 corresponds to a power input terminal portion.

The second terminal portion 34 is electrically connected to, for example, an alternator or a DC/DC converter (not shown). The second terminal portion 34 is electrically connected to a DC/DC converter if installed in, for example, a hybrid automobile, and the second terminal portion 34 is electrically connected to an alternator if installed in, for example, a gasoline automobile. Note that these are examples and can be changed as appropriate according to the specification or the like. The second terminal portion 34 is exposed from the case 31.

The third terminal portions 35 and 36 distribute power supplied from a battery or an alternator, and multiple third terminal portions 35 and 36 are provided on the bus bar 32. In the present example, the terminal portions between the first terminal portion 33 and the second terminal portion 34 are the third terminal portions 35, and the terminal portions located on the opposite side to the terminal portions 35 with the terminal portion 33 interposed therebetween are the third terminal portions 36. Multiple third terminal portions 35 and third terminal portions 36 are provided. The third terminal portions 35 and 36 are exposed from the case 31. The third terminal portions 35 and 36 correspond to power branching terminal portions.

As shown in FIG. 6, the plate-shaped conducting portions 37a and 37b have plate shapes that are elongated in the longitudinal direction of the case 31. The plate-shaped conducting portions 37a and 37b are arranged on the upper side of the case 31 (the upper side in FIG. 6), and are located above the first terminal portion 33 and the third terminal portions 35 and 36.

The plate-shaped conducting portion 37a and the plate-shaped conducting portion 37b are electrically connected by the fusing portion 38a. The fusing portion 38a has a smaller cross-sectional area than the plate-shaped conducting portions 37a and 37b, and the other terminal portions 33, 34, 35, and 36.

The first terminal portion 33 is electrically connected to the plate-shaped conducting portion 37a. In the case of the present example, the first terminal portion 33 is provided so as to extend downward from the lower end portion of the plate-shaped conducting portion 37a. Also, the third terminal portions 35 are connected to the plate-shaped conducting portion 37a via the fusing portions 38b. For this reason, the third terminal portions 35 and the first terminal portion 33 are connected via the plate-shaped conducting portion 37a and the fusing portions 38b. The fusing portions 38b extend from the lower end portion of the plate-shaped conducting portion 37a and are connected to the upper end portions of the third terminal portions 35. The fusing portions 38b have a smaller cross-sectional area than the third terminal portions 35 and the plate-shaped conducting portion 37a. That is, if excess current is supplied between the third terminal portions 35 and the plate-shaped conducting portion 37a, the fusing portions 38b are mechanically disconnected, and thus the electrical connection is removed.

The second terminal portion 34 is electrically connected to the plate-shaped conducting portion 37b. In the case of the present example, the second terminal portion 34 is provided so as to extend rearward from the plate-shaped conducting portion 37b. Also, the third terminal portions 36 are connected to the plate-shaped conducting portion 37b via the fusing portions 38c. For this reason, the third terminal portions 36 and the first terminal portion 33 are connected via the fusing portions 38a and 38c and the two plate-shaped conducting portions 37a and 37b. The fusing portions 38c extend from the lower end portion of the plate-shaped conducting portion 37b and are connected to the upper end portions of the third terminal portions 36. The fusing portions 38c have a smaller cross-sectional area than the third terminal portions 36 and the plate-shaped conducting portion 37b. That is, if excess current is supplied between the third terminal portions 36 and the plate-shaped conducting portion 37b, the fusing portions 38c are mechanically disconnected, and thus the electrical connection is removed.

As shown in FIG. 6, the case 31 includes a window portion 39 that is constituted by a transparent synthetic resin at a corresponding position, such that it is possible to easily check the states of the fusing portions 38a, 38b, and 38c, that is, whether or not they have been fused, from the outside by eyesight.

As shown in FIGS. 4 and 5, a relief terminal portion 40 is provided on the fusible link 21 so as to be attachable to and detachable from the fusible link 21.

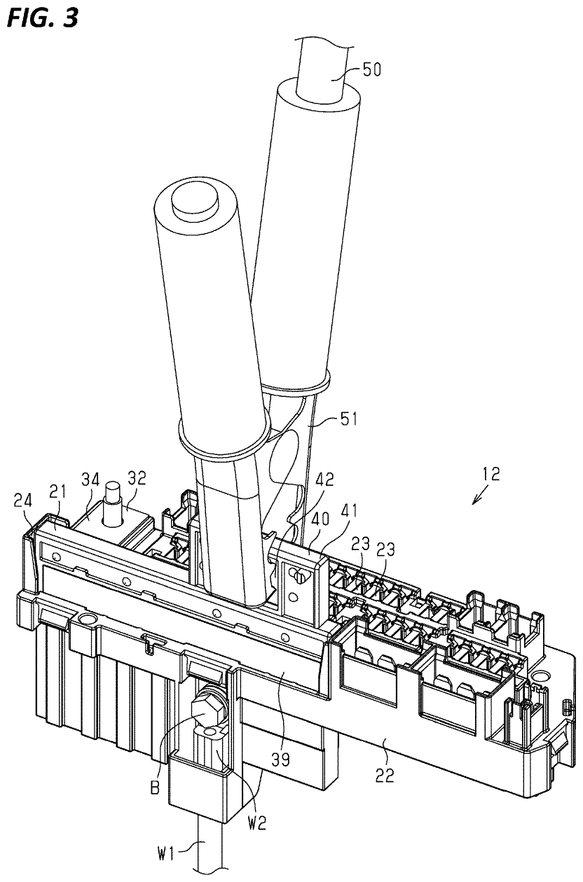

As shown in FIG. 3, the relief terminal portion 40 includes a main body portion 41 to which a clip portion 51 of the booster cable 50 is to be attached, and a connection portion 42 that is attached to the main body portion 41 and can electrically connect to the booster cable 50. The main body portion 41 is constituted by, for example, an insulating synthetic resin material. The main body portion 41 has a cuboid shape.

As shown in FIG. 5, the connection portion 42 is formed to have an L-shaped plate shape. A base end portion 42a of the connection portion 42 is held in the main body portion 41, and a distal end portion 42b of the connection portion 42 extends below the main body portion 41. A through hole 42c through which a bolt B can be inserted is provided in the distal end portion 42b.

As shown in FIGS. 5 and 7, the connection portion 42 is inserted through insertion holes 31a and 31b that are formed in the upper end surface and the lower end surface of the case 31, and the distal end portion 42b of the connection portion 42 is fixed by being fastened jointly with the first terminal portion 33 to a terminal W2 of a wire W1 by the bolt B and a nut N. That is, the relief terminal portion 40 is connected to the first terminal portion 33 serving as the power input terminal portion, without using a fusing portion. In this manner, the relief terminal portion 40 is connected on the first terminal portion 33 side with respect to the fusing portions 38a, 38b, and 38c of the power distribution bus bar 32. Accordingly, the connection portion 42 of the relief terminal portion 40, the first terminal portion 33, and the wire W1 are electrically connected. Note that the relief terminal portion 40 is separate from the fusible link 21, and therefore the relief terminal portion 40 can be omitted without performing the above-described joint fastening. That is, it is possible to change whether or not the relief terminal portion 40 is provided in the fusible link 21 of the present embodiment. For this reason, it is possible to select whether or not the relief terminal portion 40 is provided depending on the vehicle type and the like, and thus it is possible to provide a fusible link 21 that is versatile.

Also, the first terminal portion 33 that is to be electrically connected to the connection portion 42 has an opposing surface 33a that opposes the connection portion 42 of the relief terminal portion 40 and has a flat shape. For this reason, when the connection portion 42 is inserted into the insertion holes 31a and 31b, since the opposing surface 33a is a flat portion with no fusing portion and the like, it is possible to suppress a case in which the connection portion 42 of the relief terminal portion 40 is hindered by the power distribution bus bar 32 (first terminal portion 33).

Also, the fusible link 21 to which the relief terminal portion 40 is to be attached is mounted by sliding downward from above with respect to the second mounting portion 24. At this time, since the relief terminal portion 40 is located thereabove, the relief terminal portion 40 does not overlap with the first mounting portions 23 in the vertical direction.

Actions of the present embodiment will be described hereinafter.

The relay box 10 including the fusible link 21 of the present embodiment is provided with a relief terminal portion 40 that is attachable to and detachable from the fusible link 21.

Effects of the present embodiment will be described hereinafter.

(1) Due to the relief terminal portion 40 for connecting the booster cable 50 being attachable and detachable on the first terminal portion 33 side with respect to the fusing portions 38a, 38b, and 38c of the power distribution bus bar 32, the electrical connection box can be used in a state in which the relief terminal portion 40 is removed when it is not needed. For this reason, versatility can be increased.

(2) Since a configuration is used in which the relief terminal portion 40 is inserted through the insertion holes 31a and 31b located on the upper and lower portions of the case 31, it is possible to stably hold the relief terminal portion 40 using the case 31.

(3) Since the relief terminal portion 40 and the first terminal portion 33 are jointly fastened to each other, a separate configuration for electrically connecting the relief terminal portion 40 to the battery is not needed, and therefore the configuration can be made simpler.

(4) Since the opposing surface 33a of the power distribution bus bar 32 that opposes the relief terminal portion 40 has a flat shape, the relief terminal portion 40 and the opposing surface 33a can be brought into surface contact with each other when the connection portion 42 of the relief terminal portion 40 is mounted on the first terminal portion 33 of the power distribution bus bar 32. Also, due to the opposing surface 33a of the power distribution bus bar 32 being flat, it is possible to suppress a case of being hindered by the power distribution bus bar 32 when the relief terminal portion 40 is inserted through the insertion holes 31a and 31b.

(5) Since the case 31 has insertion holes through which the relief terminal portion 40 for connecting a booster cable can be inserted, the relief terminal portion 40 can be attached and detached, and thus it is possible to provide a fusible link 21 with high versatility.

### Other Embodiments

Note that the above-described embodiment can be implemented with the following modifications. The above-described embodiment and the following modified examples can be implemented in combination with each other as long as there is no technical discrepancy.

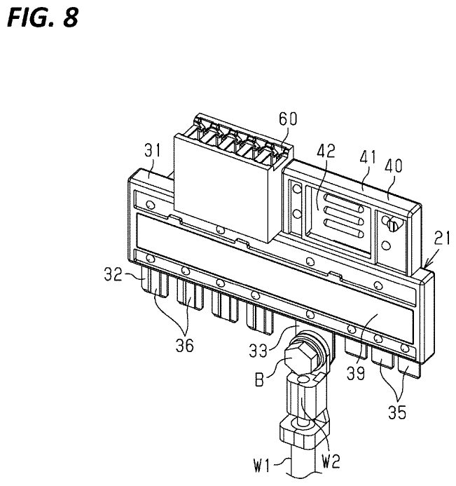

As shown in FIG. 8, a configuration may also be used in which an extended fuse part 60 is provided in one piece with the relief terminal portion 40. Accordingly, it is possible to increase the number of fuse parts that are installed. Note that the extended fuse part 60 can obtain a power supply from the battery due to having a circuit in which the relief terminal portion 40 and the connection portion 42 are electrically connected to each other.

Also, it is preferable that the extended fuse part 60 is provided at a position that does not overlap with the first mounting portions 23. By using this kind of configuration, it is possible to suppress a case in which the mounting of general-purpose fuse parts is hindered by the extended fuse part 60.

Also, it is preferable that the extended fuse part 60 is arranged so as to overlap with the fusible link 21 in the slide direction. That is, it is preferable to use a configuration in which the extended fuse part 60 overlaps with the relief terminal portion 40 in the slide direction in which the fusible link 21 is mounted by sliding. By using this kind of configuration, the relief terminal portion 40 and the extended fuse part 60 no longer overlap with the general-purpose fuse parts and the first mounting portions 23, and it is possible to suppress a case in which the mounting of the general-purpose fuse parts is hindered by the relief terminal portion 40 and the extended fuse part 60.
In the above-described embodiment, the opposing surface 33a opposing the relief terminal portion 40 had a flat shape, but various modifications are also possible, such as a recessed shape, a protruding shape, and a recessed and protruding shape. The fusing portion 38a may also be provided on the opposing surface 33a.
In the above-described embodiment, the power distribution bus bar 32 was fixed by being fastened jointly with the relief terminal portion 40 at the first terminal portion 33, but there is no limitation thereto. For example, it is also possible to use a configuration in which the relief terminal portion 40 is connected to the plate-shaped conducting portion 37a. That is, the relief terminal portion 40 is connected on the first terminal portion 33 side with respect to the fusing portions 38a, 38b, and 38c of the power distribution bus bar 32.
In the above-described embodiment, a configuration was used in which one second mounting portion 24 is provided on the fuse case 22, but it is also possible to use a configuration in which multiple second mounting portions 24 are included. In this case, it is also possible to use a configuration in which only one of the fusible links respectively mounted on the multiple second mounting portions 24 includes the relief terminal portion 40, and the relief terminal portion 40 is omitted in the other fusible links.
In the above-described embodiment, the housing 11 had a cuboid shape, but there is no limitation thereto, and the shape may also be modified as appropriate. The housing 11 may also be constituted by multiple members, although this has not been mentioned in particular.
In the above-described embodiment, a configuration was used in which the window portion 39 is provided in a portion of the case 31 of the fusible link 21, but a configuration in which the window portion 39 is omitted may also be used.
In the above-described embodiment, a configuration was used in which multiple first mounting portions 23 for mounting general-purpose fuses are provided in the fuse case 22 of the fuse block 12, but there may also be one first mounting portion 23.
In the above-described embodiment, the relay box 10 was an electrical connection box, but the fuse block 12 included in the relay box 10 may also be an electrical connection box.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. An electrical connection box comprising:
a fusible link including a power distribution bus bar having a power input terminal portion to be connected to a battery and a power branching terminal portion to be connected to the power input terminal portion via a fusing portion, and a case containing at least the fusing portion of the power distribution bus bar;
a housing including a fusible link mounting portion for mounting the fusible link; and
a relief terminal portion that can be attached and detached on the power input terminal portion side with respect to the fusing portion of the power distribution bus bar, and that is for connecting a booster cable.

2. The electrical connection box according to claim 1, wherein
the case has an insertion hole through which the relief terminal portion can be inserted.

3. The electrical connection box according to claim 1, wherein
the power distribution bus bar is fixed by being fastened jointly with the relief terminal portion at the power input terminal portion.

4. The electrical connection box according to claim 1, wherein
the power distribution bus bar has an opposing surface that opposes the relief terminal portion and has a flat shape.

5. The electrical connection box according to claim 1, wherein
an extended fuse part is provided in one piece with the relief terminal portion.

6. The electrical connection box according to claim 5, wherein
the housing includes a fuse mounting portion on which a general-purpose fuse part that is different from the extended fuse part can be mounted, and
the extended fuse part is provided at a position that does not overlap with the fuse mounting portion in a state in which the relief terminal portion is mounted on the power distribution bus bar.

7. The electrical connection box according to claim 6, wherein
the fusible link is mounted by sliding on the fusible link mounting portion, and
the relief terminal portion and the extended fuse part are arranged at positions overlapping in a slide direction of the fusible link.

8. A fusible link comprising:
a power distribution bus bar including a power input terminal portion to be connected to a battery and a power branching terminal portion to be connected to the power input terminal portion via a fusing portion; and a case that contains at least the fusing portion of the power distribution bus bar,
wherein the case has an insertion hole through which a relief terminal portion for connecting a booster cable can be inserted.
